(19) United States
(12) Patent Application Publication
(10) Pub. No.: US 2008/0057638 A1
(43) Pub. Date: Mar. 6, 2008

(54) METHOD OF MANUFACTURING A FLASH MEMORY DEVICE

(75) Inventor: Min Sik JANG, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/616,017

(22) Filed: Dec. 26, 2006

(30) Foreign Application Priority Data
Sep. 6, 2006 (KR) 2006-85715

(51) Int. Cl. H01L 21/8238

(52) U.S. Cl. 438/218

(57) ABSTRACT

A method of manufacturing a flash memory device includes etching portions of a tunnel oxide layer, a first polysilicon layer, a hard mask layer and a semiconductor substrate all of which are laminated over a semiconductor substrate to form trenches. The trenches are filled with an insulating layer thereby forming isolation layers. A portion of top surfaces of the isolation layers is removed, thereby controlling an effective field height (EFH) of the isolation layers while partially exposing sides of the first polysilicon layer. An oxide layer for spacers is formed on the surface of each isolation layer including the exposed first polysilicon layer by using DCS as a source gas. An etch process is performed so that the oxide layer remains only on the sides of the first polysilicon layer, thereby forming spacers. The isolation layers between the spacers are etched to a thickness. The spacers are removed. A dielectric layer and a second polysilicon layer are formed on the surface of each isolation layer.

### CROSS-REFERENCES TO RELATED APPLICATIONS

The present application claims priority to Korean patent application number 10-2006-085715, filed on Sep. 6, 2006, which is incorporated herein by reference in its entirety.

### BACKGROUND OF THE INVENTION

The present invention relates generally to flash memory devices, and more particularly to a method of manufacturing a flash memory device, which reduces interference charges between floating gates.

In recent years, in the manufacture of NAND flash memory, as the level of integration of devices increases, the space in which a unit active region and a unit field region are formed decreases in size. Since a dielectric layer (including a floating gate, a control gate, and so on) is formed within a narrow active space, the distance between the gates is reduced. Accordingly, interference becomes problematic.

In particular, in a general NAND flash memory device to which an Advanced Self-Aligned Trench Isolation (STI) is applied, interference charges between the floating gates must be reduced in order to develop multi-level cells (MLCs).

FIG. 1 is a perspective view illustrating a method of manufacturing a general NAND flash memory device by employing an advanced STI.

Referring to FIG. 1, a tunnel oxide layer 2 and a first polysilicon layer 3 are formed over a semiconductor substrate 1. The first polysilicon layer 3, the tunnel oxide layer 2 and the semiconductor substrate 1 are sequentially etched by means of an etch process employing an isolation mask, thereby forming trenches.

An insulating layer, for example, a High Density Plasma (HDP) oxide layer is formed on the entire surface to fill the trenches. The insulating layer is polished (for example, by means of Chemical Mechanical Polishing (CMP)) so that a top surface of the first polysilicon layer 3 is exposed, thereby forming isolation layers 4 within the trenches.

A second polysilicon layer 5 is formed on the entire surface. The second polysilicon layer 5 is etched using a mask, thereby forming a floating gate including the first polysilicon layer 3 and the second polysilicon layer 5. A dielectric layer 6 and a conductive layer 7 for a control gate are formed on the entire surface.

If the floating gate is formed by the above method, the width of the isolation layer is reduced due to the higher-integration of devices. Accordingly, the distance between neighboring floating gates is decreased, and interference charges are generated due to the decreased distance between neighboring floating gates.

In order to reduce an interference charge (C_{fgy}) between the floating gates, the height of the insulating layer between the floating gates is lowered.

If the height of the insulating layer is lowered to at least a given thickness, the distance between the semiconductor substrate 1 and the control gate 7 is decreased, resulting in a reduction in the breakdown voltage. Therefore, the interference charges must be reduced while maintaining the thickness of the insulating layer on the sides of the floating gate at a given value.

One of the methods for reducing the interference charges is to lower the height of the isolation layer between spacers in which the dielectric layer and the control gate are formed after the spacers are formed on the sidewalls of the floating gate.

FIG. 2 is a cross-sectional view for illustrating a method of manufacturing a general NAND flash memory device by employing a process of forming spacers on sidewalls of a floating gate.

Referring to FIG. 2, a tunnel oxide layer 11, a first polysilicon layer 12 for a floating gate, a buffer oxide layer (not shown) and a nitride layer (not shown) are sequentially formed over a semiconductor substrate 10. Portions of the nitride layer (not shown), the buffer oxide layer (not shown), the first polysilicon layer 12, the tunnel oxide layer 11 and the semiconductor substrate 10 are etched by means of an etch process to form trenches. A HDP oxide layer is formed on the entire surface so that the trenches are filled.

A polishing process is performed until a top surface of the nitride layer is exposed, thereby forming an isolation layer 13. A portion of a top surface of the isolation layer 13 is etched in order to control the Effective Field Height (EFH) of the isolation layer 13. After the nitride layer and the buffer oxide layer are removed, spacers are formed on the sidewalls of the exposed first polysilicon layer 12. A top surface of the isolation layer 13 is partially removed using the spacers as masks, thereby removing the spacers. A dielectric layer 14 and a second polysilicon layer 15 for a control gate are sequentially formed on the entire surface.

At the time of the spacer removal process, a wet etch process is performed. The spacer and the isolation layer 13 have a similar wet etch rate. Thus, when the spacers are removed, they are removed together with the isolation layer 13 formed below the spacers. Accordingly, the height of the isolation layer 13 is lower than that of the tunnel oxide layer 11. Thus, the distance between the semiconductor substrate 10 and the control gate 15 is minimized, resulting in a weak structure in which the breakdown voltage is very low.

### BRIEF SUMMARY OF THE INVENTION

Embodiments of the present invention are directed to a method of manufacturing a NAND flash memory device, in which spacers are formed on the sides of an exposed floating gate. A dry etch process is performed so that a central portion of an isolation layer is relatively lowered. The spacers are removed by means of a wet etch process, thereby reducing interference charges between floating gates.

In one embodiment, a method of manufacturing a NAND flash memory device includes etching portions of a tunnel oxide layer, a first polysilicon layer, a hard mask layer and a semiconductor substrate all of which are laminated over a semiconductor substrate, thereby forming trenches. The trenches are filled with an insulating layer, thereby forming isolation layers. A portion of top surfaces of the isolation layers is removed, thereby controlling an effective field height (EFH) of the isolation layers while partially exposing sides of the first polysilicon layer. An oxide layer for spacers is formed on the surface of each isolation layer including the exposed first polysilicon layer by using dichlorosilane (DCS) as a source gas. An etch process is performed so that the oxide layer remains on the sides of the first polysilicon layer, thereby forming spacers. The isolation layers between the spacers are etched to a thickness. The spacers are removed. A dielectric layer and a second polysilicon layer are then formed on the surface of each isolation layer.

The first polysilicon layer may be formed using a doped polysilicon layer, or a dual structure of an undoped polysilicon layer and a doped polysilicon layer.

The hard mask layer may comprise a buffer oxide layer and a nitride layer.

The method may further comprise removing the hard mask layer before the oxide layer may be formed.

The oxide layer may be formed by means of a single wafer type Low Pressure Chemical Vapor Deposition (LP-CVD).

The oxide layer may be formed in a temperature range of 700 to 850 degrees Celsius and a pressure range of 50 to 500 torr.

The oxide layer may be formed to a thickness of 200 to 500 angstrom.

When the oxide layer is formed, a silicon source gas may employ DCS SiH₂Cl₂, an oxygen source gas may employ N₂O, and a carrier and purge source gas may employ N₂.

The ratio of the source gases, N₂O and DCS, may be set in the range of 20:1 to 3000:1.

The oxide layer may include silicon and oxygen at a ratio of 1:1.9 to 1:2.5 and having a refractive index of 1.4 to 1.45.

The spacers may be formed by a dry etch process.

The spacers may be removed by a wet etch process employing BOE or HF.

At the time of the spacer removal process, the wet etch rate may be set within a range of three times to two hundred times.

### BRIEF DESCRIPTION OF THE DRAWINGS

FIG. 1 is a perspective view illustrating a method of manufacturing a general NAND flash memory device by employing advanced STI.

FIG. 2 is a cross-sectional view illustrating a method of manufacturing a general NAND flash memory device by employing a process of forming spacers on sidewalls of a floating gate.

FIGS. 3A to 3F are cross-sectional views illustrating a method of manufacturing a NAND flash memory device by employing STI according to an embodiment of the present invention.

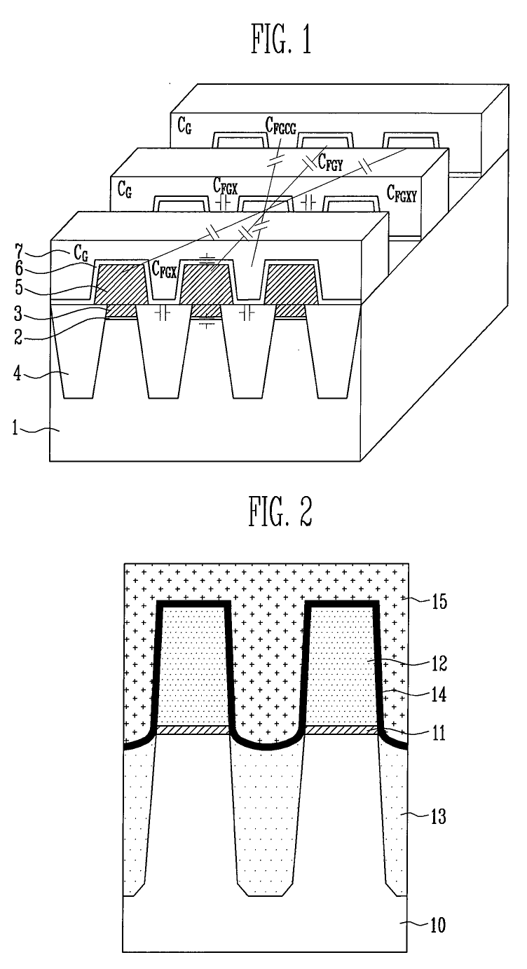

### DESCRIPTION OF SPECIFIC EMBODIMENTS

Specific embodiments according to the present invention will be described with reference to the accompanying drawings.

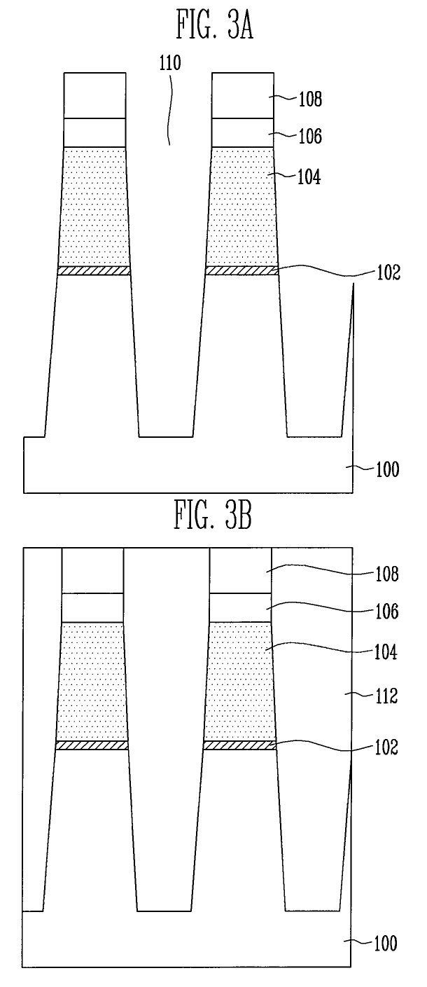

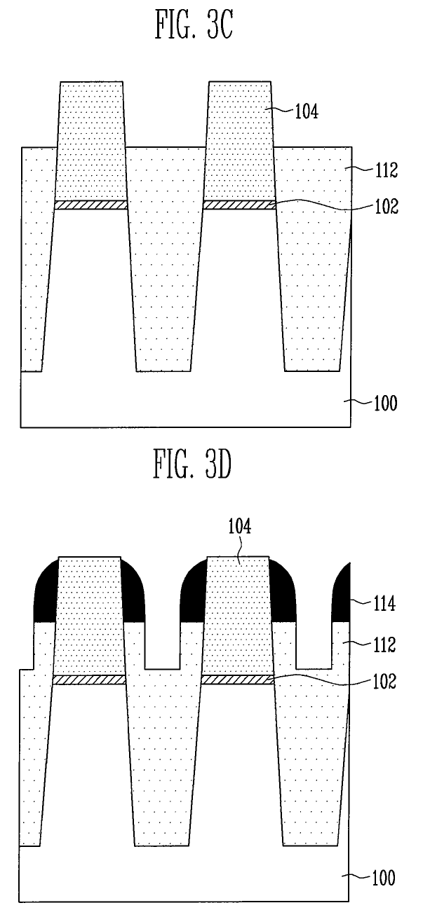

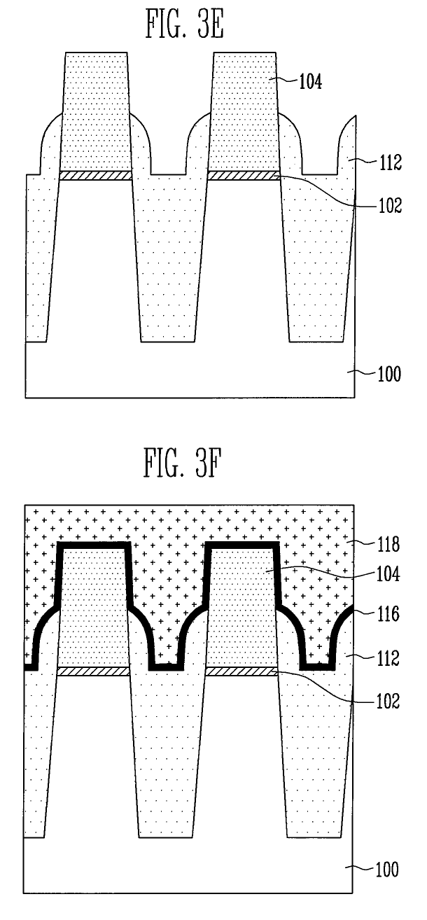

FIGS. 3A to 3F are cross-sectional views for illustrating a method of manufacturing a NAND flash memory device by employing STI according to an embodiment of the present invention.

Referring to FIG. 3A, a tunnel oxide layer 102, a first polysilicon layer 104 for a floating gate, a buffer oxide layer 106 for a hard mask and a nitride layer 108 for a hard mask are sequentially formed over a semiconductor substrate 100. The first polysilicon layer 104 may be formed using a doped polysilicon layer, or a dual structure of an undoped polysilicon layer and a doped polysilicon layer. The buffer oxide layer 106 prevents damage from occurring on the surface of the first polysilicon layer 104 due to phosphoric acid when removing the nitride layer 108 (i.e., a subsequent process). The buffer oxide layer 106 may be omitted, if appropriate.

Portions of the nitride layer 108, the buffer oxide layer 106, the first polysilicon layer 104, the tunnel oxide layer 102 and the semiconductor substrate 100 are etched by means of an exposure process and a dry etch process, thereby forming trenches 110.

Referring to FIG. 3B, an oxidization process is performed on the sidewalls of the trenches 110 including the first polysilicon layer 104 in order to eliminate any damage incurred by the dry etch process. The oxidization process is performed using a radical method. The radical method is used to prevent the reoxidization of the first polysilicon layer 104 when general dry and wet oxidization processes are performed.

An insulating layer is formed on the surface so that the trenches 110 are gap-filled. The insulating layer may be formed using a HDP oxide layer including a single layer or multiple layers by means of a Chemical Vapor Deposition (CVD), Physical Vapor Deposition (PVD) or Solid Phase Grain (SPG) method.

A CMP process is performed so that a top surface of the nitride layer is exposed, thereby forming isolation layers 112. The CMP process may not be performed until an annealing process is performed in order to increase the density of the insulating layer.

Referring to FIG. 3C, the top surfaces of the isolation layers 112 are partially etched by means of a wet etch process using buffered oxide echant (BOE) or hydrofluoric acid (HF) in order to control the EFH of the isolation layers 112.

A wet etch process using phosphoric acid is then performed to remove the nitride layer 108. At the time of the removal process of the nitride layer 108, an etch target is set to 150% to 170% of a deposition thickness. A top surface of the buffer oxide layer 106 is partially removed because of the etch selectivity of the nitride layer 108 and the buffer oxide layer 106. Since the buffer oxide layer 106 is formed on the first polysilicon layer 104, the surface of the first polysilicon layer 104 is not damaged at the time of removal of the nitride layer 108. The remaining buffer oxide layer 106 is removed by means of a wet etch process.

Referring to FIG. 3D, an oxide layer for a spacer is formed on the entire surface. The oxide layer may be formed to a thickness of 200 to 500 angstroms by means of a single wafer type Low Pressure Chemical Vapor Deposition (LP-CVD) in a temperature range of 700 to 850 degrees Celsius and a pressure range of 50 to 500 torr. A source gas is applied by means of a showerhead method. The source gas may include a silicon source gas, an oxygen source gas, and a carrier and purge source gas. The silicon source gas employs DCS SiH₂Cl₂, the oxygen source gas employs N₂O, and the carrier and purge source gas employs N₂. The ratio of the source gases, N₂O and DCS, may be set to a range of between 20:1 and 3000:1.

If the LP-CVD method is employed as a furnace type in the same manner as an existing method in the process of forming the oxide layer, no problems occur at the time of a dry etch process, but a wet etch process is not performed at high speed at the time of a spacer removal process (i.e., a subsequent process). Thus, if the LP-CVD is used as the single wafer type as describe above at the time of forming the oxide layer, the wet etch rate may increase at the time of the spacer removal process (i.e., a subsequent process).

Furthermore, the wet etch rate at the time of the spacer removal process may further increase by not using MS, TEOS or TCS, but rather using DCS SiH₂Cl₂ as the silicon source gas. In other words, since the oxide layer is formed using DCS as the source gas, the wet etch rate at the time of the spacer removal process increases. Furthermore, since the oxide layer is formed by the LP-CVD method as the single wafer type, the wet etch rate further increases at the time of the spacer removal process.

If the ratio of the source gas, N₂O and DCS, is set between 20:1 and 3000:1 when forming the oxide layer as described above, the ratio of silicon to oxygen is between 1:2 and 1:2.1 and a refractive index is between 1.45 and 1.46. However, in the oxide layer of the present invention, the ratio of silicon to oxygen is between 1:1.9 and 1:2.5 and a refractive index is between 1.4 and 1.45. Thus, in the present invention, the refractive index is low when compared with the existing method.

A dry etch process is performed on the oxide layer, thereby forming spacers 114 on the sidewalls of the first polysilicon layer 104. The isolation layers 112 are etched between the spacers 114 using the spacers 114 as masks at a given thickness. At the time of the dry etch process, the oxide layer has a similar etch selectivity to that of the oxide layer formed by the LP-CVD method or the oxide layer formed by the plasma method. A given thickness of the isolation layers 112 can be etched, but the isolation layers 112 under the spacer 114 are not etched when the spacers 114 are formed.

Referring to FIG. 3E, the spacers 114 are removed by a wet etch process using BOE or HF. Since the spacers 114 are formed as an oxide layer formed using DCS as a source, the wet etch rate increases by three times to two hundred times when compared with a general oxide layer at the time of the removal process of the spacers 114. A wet etch process time is set to a minimal time at which the spacers 114 can be removed.

Referring FIG. 3F, a dielectric layer 116 and a second polysilicon layer 118 for a control gate are sequentially formed on the surface.

As described above, the oxide layer is formed using DCS as the source gas, and the dry etch process is performed to form the spacers 114 on the sidewalls of the first polysilicon layer 104 and also to lower the height of the isolation layers 112 between the spacers 114. The spacers 114 are removed by the wet etch process. It is therefore possible to reduce interference charges between the floating gates. Accordingly, MLCs can be implemented in NAND flash memory devices of 50 nm or less in size.

As described above, according to the present invention, the oxide layer for the spacer is formed by the single wafer type LP-CVD. The dry etch process is performed to form the spacers on the sidewalls of the first polysilicon layer and also to lower the central portion of the isolation layers relatively. The spacers are removed by the wet etch process. Accordingly, interference charges between the floating gates can be reduced.

Since interference charges are reduced, MLCs can be implemented in NAND flash memory devices of 50 nm or less in size.

The above embodiments of the present invention are illustrative and not limitative. Various alternatives and equivalents are possible. Other additions, subtractions, or modifications are obvious in view of the present disclosure and are intended to fall within the scope of the appended claims.

What is claimed is:

1. A method of manufacturing a flash memory device, comprising:
etching portions of a tunnel oxide layer, a first polysilicon layer, a hard mask layer and a semiconductor substrate, all of which are laminated over a semiconductor substrate, wherein the etching forms trenches;
filling the trenches with an insulating layer, thereby forming isolation layers;
removing a portion of top surfaces of the isolation layers, thereby controlling an effective field height (EFH) of the isolation layers while partially exposing sides of the first polysilicon layer;
forming an oxide layer for spacers on the surface of each isolation layer including the exposed first polysilicon layer by using DCS as a source gas;
performing an etch process so that the oxide layer remains on the sides of the first polysilicon layer, thereby forming spacers;
etching the isolation layers between the spacers to a thickness;
removing the spacers; and
forming a dielectric layer and a second polysilicon layer on the surface of each isolation layer.

2. The method of claim 1, wherein the first polysilicon layer is formed using one of: a doped polysilicon layer or a dual structure comprising an undoped polysilicon layer and a doped polysilicon layer.

3. The method of claim 1, wherein the hard mask layer includes a buffer oxide layer and a nitride layer.

4. The method of claim 1, further comprising removing the hard mask layer before the oxide layer is formed.

5. The method of claim 1, wherein the oxide layer is formed by means of a single wafer type Low Pressure Chemical Vapor Deposition (LP-CVD).

6. The method of claim 5, wherein the oxide layer is formed in a temperature range of 700 to 850 degrees Celsius and a pressure range of 50 to 500 torr.

7. The method of claim 5, wherein the oxide layer is formed to a thickness of 200 to 500 angstroms.

8. The method of claim 5, wherein when the oxide layer is formed, a silicon source gas employs DCS SiH₂Cl₂, an oxygen source gas employs N₂O, and a carrier and purge source gas employs N₂.

9. The method of claim 8, wherein the ratio of the source gases, N₂O and DCS, is set to a range of between 20:1 and 3000:1.

10. The method of claim 1, wherein the oxide layer includes silicon and oxygen at a ratio of between 1:1.9 and 1:2.5 and with a refractive index of between 1.4 and 1.45.

11. The method of claim 1, wherein the spacers are formed by a dry etch process.

12. The method of claim 1, wherein the spacers are removed by a wet etch process employing BOE or HF.

13. The method of claim 12, wherein at the time of the spacer removal process, the wet etch rate is set within a range of three times to two hundred times.
